(19) United States
(12) Patent Application Publication
(10) Pub. No.: US 2024/0096980 A1
(43) Pub. Date: Mar. 21, 2024

(54) SEMICONDUCTOR DEVICE

(71) Applicant: SAMSUNG ELECTRONICS CO., LTD., Suwon-si (KR)

(72) Inventors: Inyeal LEE, Suwon-si (KR); Deokhan BAE, Suwon-si (KR); Juyoun KIM, Suwon-si (KR)

(21) Appl. No.: 18/368,725

(22) Filed: Sep. 15, 2023

(30) Foreign Application Priority Data
Sep. 19, 2022 (KR) 10-2022-0118088

(51) Int. Cl. H01L 29/417; H01L 29/06; H01L 29/423; H01L 29/775; H01L 29/786

(52) U.S. Cl. CPC H01L 29/41733; H01L 29/0673; H01L 29/42392; H01L 29/775; H01L 29/78696

(57) ABSTRACT

A semiconductor device includes an active pattern on a substrate with first and second regions; first and second source/drain regions on the first and second regions; first and second source/drain contacts on the first and second source/drain regions; and a separation structure intersecting the active pattern between the first and second source/drain contacts, and extending into the active pattern between the first and second source/drain regions, wherein an upper surface of the second source/drain contact is higher than an upper surface of the first source/drain contact, and wherein the separation structure has an asymmetrical structure having an upper surface of a first portion adjacent to the first source/drain contact higher than an upper surface of a second portion adjacent to the second source/drain contact.

### CROSS-REFERENCE TO RELATED APPLICATION

This application claims benefit of priority to Korean Patent Application No. 10-2022-0118088, filed on Sep. 19, 2022, in the Korean Intellectual Property Office, the disclosure of which is incorporated herein by reference in its entirety.

### BACKGROUND

### 1. Field

Example embodiments of the present disclosure relate to a semiconductor device.

### 2. Description of the Related Art

As demands for high performance, high speed, and/or multifunctionality of semiconductor devices have increased, integration density of a semiconductor device has increased. In manufacturing a semiconductor device with a fine pattern corresponding to the trend for high integration density of semiconductor devices, it has been necessary to implement patterns having a fine width or a fine spacing distance. Also, to overcome limitations of operating characteristics due to size reductions of a planar metal oxide semiconductor FET (MOSFET), there have been efforts to develop a semiconductor device including a FinFET having a three-dimensional channel structure.

### SUMMARY

According to an example embodiment of the present disclosure, a semiconductor device includes an active pattern disposed on a substrate, and including a first region and a second region; a first source/drain region on the first region and a second source/drain region on the second region; a first source/drain contact on the first source/drain region; a second source/drain contact on the second source/drain region; and a separation structure intersecting the active pattern between the first and second source/drain contacts, and extending into the active pattern between the first and second source/drain regions, wherein an upper surface of the second source/drain contact is higher than an upper surface of the first source/drain contact, and wherein the separation structure has an asymmetrical structure in which an upper surface of a first portion adjacent to the first source/drain contact is higher than an upper surface of a second portion adjacent to the second source/drain contact.

According to an example embodiment of the present disclosure, a semiconductor device includes active patterns extending in a first direction on a substate; source/drain regions on each of the active patterns; source/drain contacts respectively on the source/drain regions; and a separation structure extending in a second direction intersecting the first direction between adjacent source/drain contacts among the source and drain contacts, and extending into the active pattern between the first and second source/drain regions in in a vertical direction perpendicular to the upper surface of the substrate, wherein the adjacent source/drain contacts include first and second source/drain contacts adjacent to each other, and third and fourth source/drain contacts adjacent to each other, wherein an upper surface of the second source/drain contact is higher than an upper surface of the first source/drain contact, and an upper surface of the third source/drain contact has substantially a same level as an upper surface of the fourth source/drain contact wherein the separation structure includes a first separation structure between the first and second source/drain contacts; and a second separation structure between the third and fourth source/drain contacts, and wherein, in a cross section along the first direction, the first separation structure has an asymmetric structure, and the second separation structure has a symmetrical structure.

According to an example embodiment of the present disclosure, a semiconductor device includes an active pattern disposed on a substrate, and extending in a first direction; a gate structure crossing the active pattern, and extending in a second direction intersecting the first direction; a separation structure intersecting the active pattern, and extending in a vertical direction perpendicular to the upper surface of the substrate; a first source/drain region on the active pattern between the gate structure and a first side of the separation structure; a second source/drain region on the active pattern at a second side of the separation structure; a first source/drain contact on the first source/drain region; and a second source/drain contact on the second source/drain region, wherein one of the first and second source/drain contacts has an upper surface higher than an upper surface of the gate structure, and the other of the first and second source/drain contacts has an upper surface lower than the upper surface of the gate structure, and wherein the separation structure has an asymmetrical structure in which an upper surface of a first portion adjacent to the one of the first and second source/drain contacts is higher than an upper surface of a second portion adjacent to the other of the first and second source/drain contacts.

### BRIEF DESCRIPTION OF DRAWINGS

Features will become apparent to those of skill in the art by describing in detail exemplary embodiments with reference to the attached drawings, in which:

FIG. 1 is a plan view illustrating a semiconductor device according to an example embodiment of the present disclosure;

FIG. 2 is a cross-sectional view illustrating a semiconductor device according to an example embodiment of the present disclosure;

FIG. 3 is a cross-sectional view illustrating a semiconductor device according to an example embodiment of the present disclosure;

FIG. 4 is an enlarged plan view illustrating a portion of a semiconductor device according to an example embodiment of the present disclosure;

FIG. 5 is a cross-sectional view illustrating a semiconductor device according to an example embodiment of the present disclosure;

FIG. 6 is a cross-sectional view illustrating a semiconductor device according to an example embodiment of the present disclosure;

FIG. 7 is an enlarged plan view illustrating a portion of a semiconductor device according to an example embodiment of the present disclosure;

FIG. 8 is a cross-sectional view illustrating a semiconductor device according to an example embodiment of the present disclosure;

FIG. 9 is a cross-sectional view illustrating a semiconductor device according to an example embodiment of the present disclosure;

FIG. 10 is a cross-sectional view illustrating a semiconductor device according to an example embodiment of the present disclosure;

FIG. 11 is an enlarged plan view illustrating a portion of a semiconductor device according to an example embodiment of the present disclosure;

FIG. 12 is a cross-sectional view illustrating a semiconductor device according to an example embodiment of the present disclosure;

FIG. 13 is a cross-sectional view illustrating a semiconductor device according to an example embodiment of the present disclosure;

FIG. 14 is a cross-sectional view illustrating a semiconductor device according to an example embodiment of the present disclosure; and

FIGS. 15A to 15I are cross-sectional views of stages in a method of manufacturing a semiconductor device according to an example embodiment of the present disclosure.

### DETAILED DESCRIPTION

Hereinafter, embodiments of the present disclosure will be described as follows with reference to the accompanying drawings.

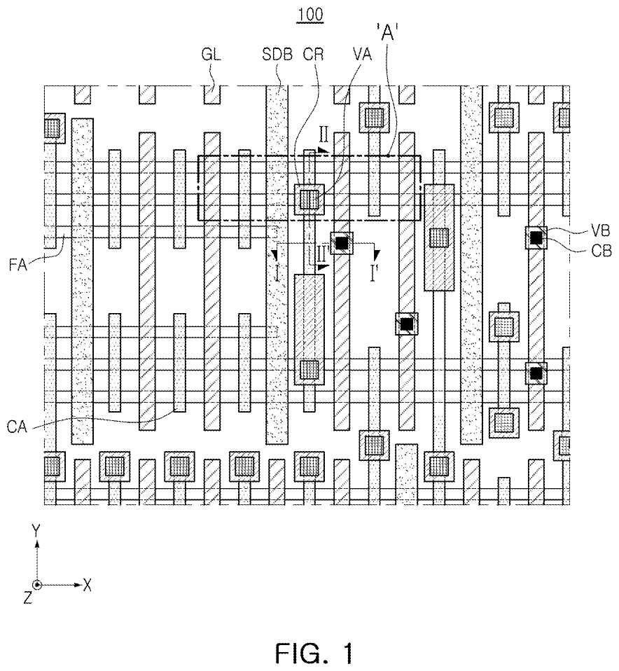

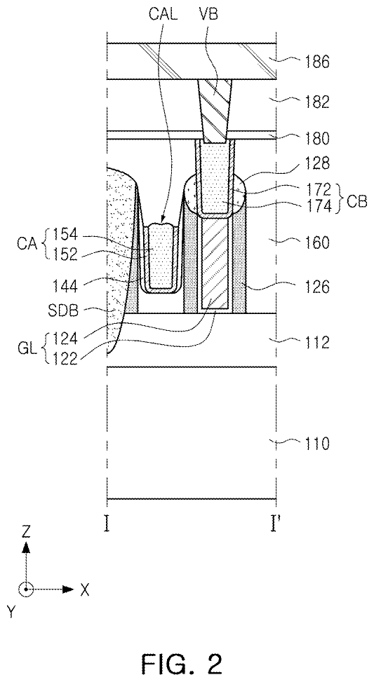

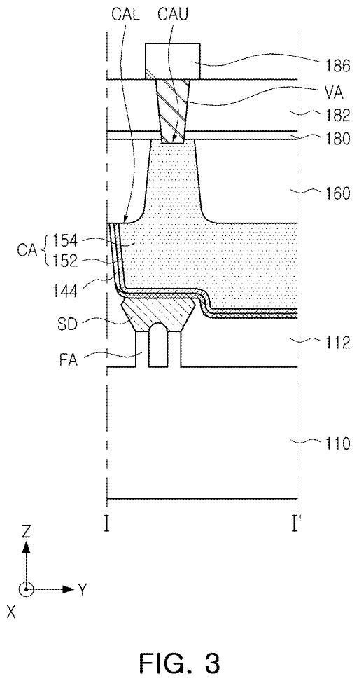

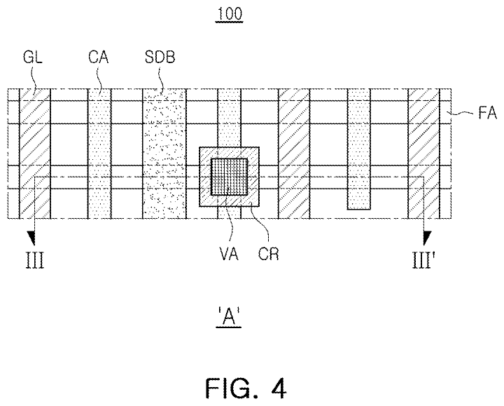

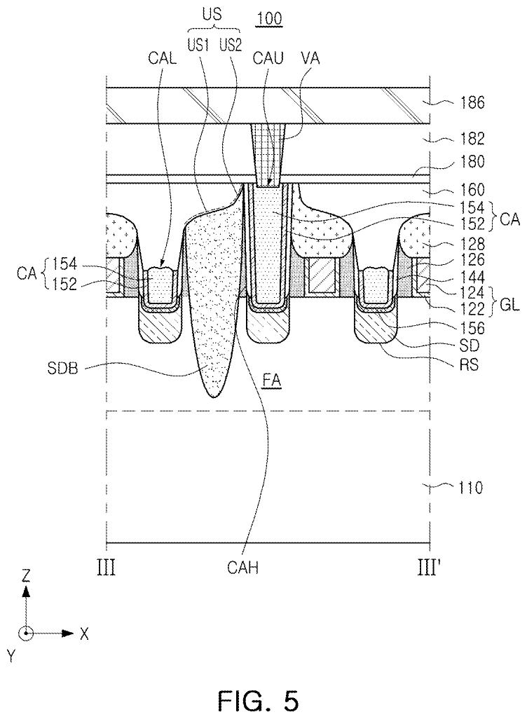

FIG. 1 is a plan view illustrating a semiconductor device according to an example embodiment. FIG. 2 is a cross-sectional view along line I-I′ in FIG. 1. FIG. 3 is a cross-sectional view along line II-IF in FIG. 1. FIG. 4 is an enlarged plan view illustrating region “A” in FIG. 1. FIG. 5 is a cross-sectional view along line in FIG. 4.

Referring to FIGS. 1 to 5, a semiconductor device 100 may include a substrate 110, active patterns FA extending on the substrate 110, gate lines GL extending by intersecting the active patterns FA on the substrate 110, source/drain regions SD disposed on the active patterns FA on at least one side of the gate lines GL, a source/drain contact CA connected to the source/drain regions SD, and a separation structure SDB between the source/drain regions SD.

The substrate 110 may have an upper surface extending in the first direction X and the second direction Y. The substrate 110 may include a semiconductor material, e.g., a group IV semiconductor, a group III-V compound semiconductor, or a group II-VI compound semiconductor. For example, the group IV semiconductor may include silicon, germanium, or silicon-germanium. The substrate 110 may be provided as a bulk wafer, an epitaxial layer, a silicon on insulator (SOI) layer, or a semiconductor on insulator (SeOI) layer.

The semiconductor device 100 may further include a device isolation layer 112 defining the active patterns FA. The active patterns FA may protrude from the upper surface of the substrate 110 and may extend in the first direction X on the substrate 110. The active patterns FA may be formed as a portion of the substrate 110 or may include an epitaxial layer grown from the substrate 110. The active patterns FA on the substrate 110 may be partially recessed into both sides of the gate lines GL, and the source/drain regions SD may be disposed on the recessed active patterns FA. The active patterns FA may include impurities or doped regions including impurities.

The gate lines GL may intersect the active patterns FA on the substrate 110 and may extend in the second direction Y. The gate lines GL may include a gate insulating layer 122 and a gate electrode 124. Gate spacers 126 may be disposed on sidewalls of the gate lines GL, and a gate capping layer 128 may be disposed on the gate lines GL and the gate spacers 126.

The gate electrode 124 may include, e.g., doped polysilicon, a metal, a conductive metal nitride, a conductive metal carbide, a conductive metal silicide, or a combination thereof. For example, the gate electrode 124 may be formed of Al, Cu, Ti, Ta, W, Mo, TaN, NiSi, CoSi, TiN, WN, TiAl, TiAlN, TaCN, TaC, TaSiN, or combinations thereof.

The gate insulating layer 122 may be disposed on a bottom surface and sidewalls of the gate electrode 124. The gate insulating layer 122 may be interposed between the gate electrode 124 and the active patterns FA, and between the gate electrode 124 and the upper surface of the device isolation layer 112. The gate insulating layer 122 may include, e.g., a silicon oxide film, a silicon oxynitride film, a high-K dielectric film having a dielectric constant higher than that of a silicon oxide film, or a combination thereof. The high dielectric layer may be formed of, e.g., metal oxide or metal oxynitride. For example, the high dielectric film usable as the gate insulating layer 122 may be formed of HfO₂, HfSiO, HfSiON, HfTaO, HfTiO, HfZrO, ZrO₂, Al₂O₃, or a combination thereof.

The gate spacers 126 may cover both sidewalls of the gate lines GL and may extend in the second direction Y. The gate spacers 126 may include, e.g., silicon oxide (SiOₓ), silicon nitride (SiNₓ), silicon oxynitride (SiOₓN_{y}), silicon carbonitride (SiCₓN_{y}), silicon oxycarbonitride (SiOₓC_{y}N_{z}) or a combination thereof.

In example embodiments, the gate spacers 126 may include a plurality of layers formed of different materials. For example, as illustrated in FIG. 5, the gate spacers 126 are formed in a single layer. In another example, the gate spacers 126 may include a first spacer layer, second spacer layer, and a third spacer layer stacked in order on the sidewall of the gate electrode 124. In example embodiments, the first spacer layer and the third spacer layer may include silicon nitride, silicon oxide, or silicon oxynitride. The second spacer layer may include an insulating material having a lower dielectric constant than that of the first spacer layer. In example embodiments, the second spacer layer may include an air space.

The gate capping layer 128 may cover upper surfaces of the gate lines GL and the gate spacers 126 and may extend in the second direction Y. In example embodiments, the gate capping layer 128 may include silicon nitride or silicon oxynitride. As illustrated in FIG. 5, at least a portion of the gate capping layer 128 may have an uneven upper surface. For example, at least a portion of the gate capping layer 128 may have a convex upper surface protruding upwardly, and a level of the upper surface of the portion of the gate capping layer 128 disposed on the gate electrode 124 may be higher than a level of the upper surface of the portion of the gate capping layer 128 disposed on the gate spacers 126.

Recess regions RS extending into the active patterns FA on both sides of the gate lines GL may be formed, and source/drain regions SD may be formed in the recess regions RS. For example, the source/drain regions SD may have a plurality of inclined sidewalls.

The source/drain regions SD may include, e.g., a doped SiGe layer, a doped Ge layer, a doped SiC layer, or a doped InGaAs layer. The recess regions RS may be formed by removing portions of the active patterns FA on both sides of the gate lines GL, and the source/drain regions SD may be formed by growing a semiconductor layer filling the recess regions RS through an epitaxial process. In example embodiments, when the active patterns FA are active patterns for NMOS transistors, the source/drain regions SD may include doped Si, and when the active patterns FA are active patterns for PMOS transistors, the source/drain regions SD may include doped SiGe.

In example embodiments, the source/drain regions SD may include a plurality of semiconductor layers having different compositions. For example, the source/drain regions SD may include a lower semiconductor layer, an upper semiconductor layer, and a capping semiconductor layer filling the recess regions RS in sequence.

An etch stop film may be further formed on the sidewalls of the source/drain regions SD, the sidewalls of the source/drain regions SD, and the upper surface of the device isolation layer 112. The etch stop film may include at least one of, e.g., silicon nitride, silicon oxynitride, silicon oxycarbonitride, and silicon oxide.

An inter-gate insulating layer covering the source/drain regions SD may be formed between the gate lines GL, e.g., in regions between adjacent gate lines GL in the first direction X and adjacent source/drain contacts CA in the second Y direction.

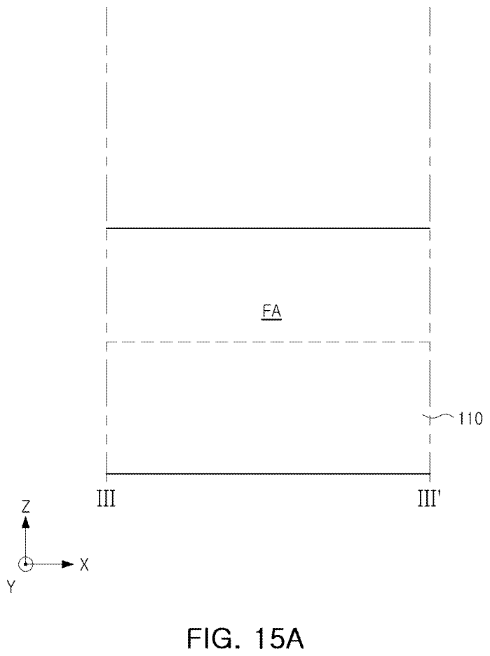

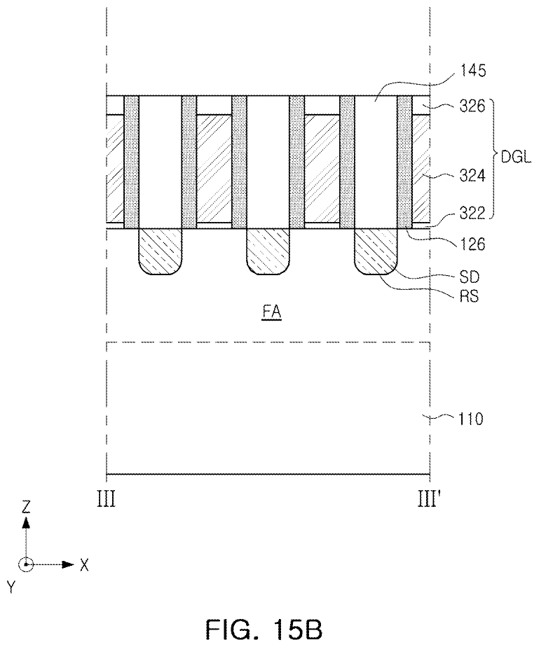

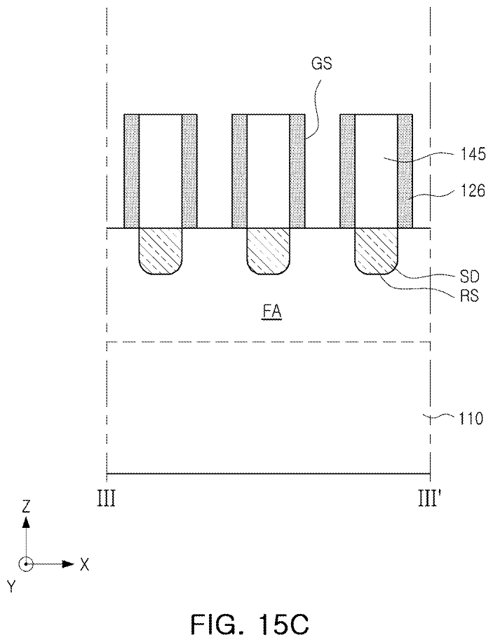

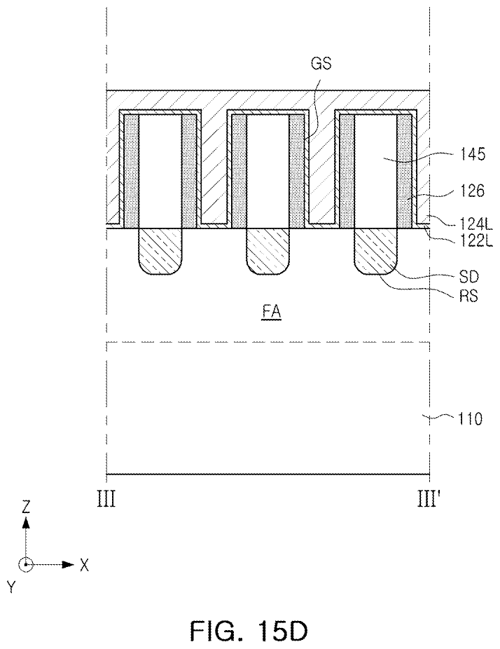

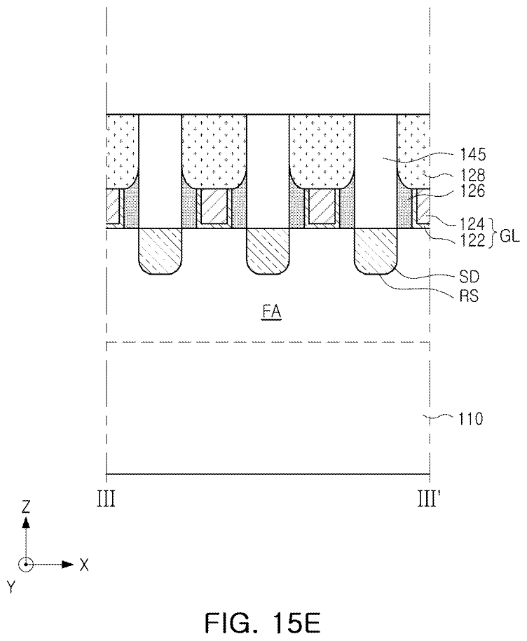

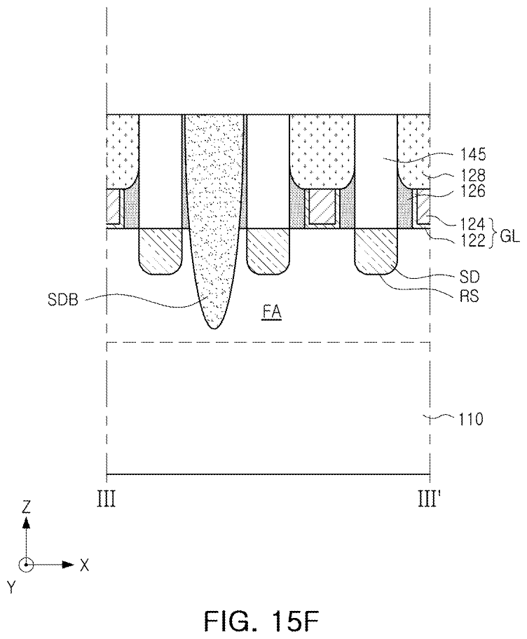

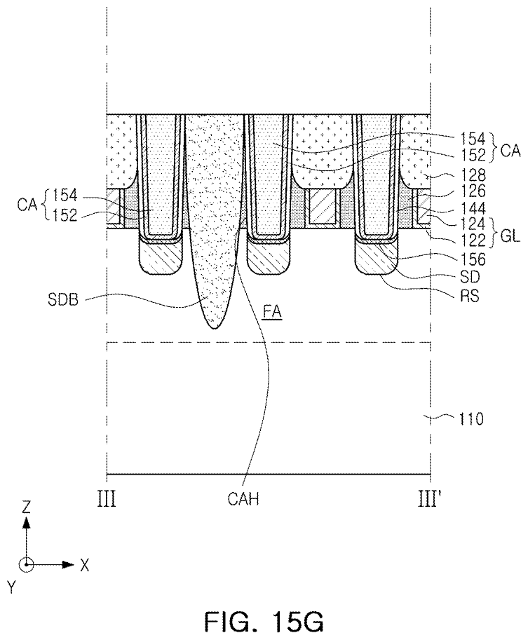

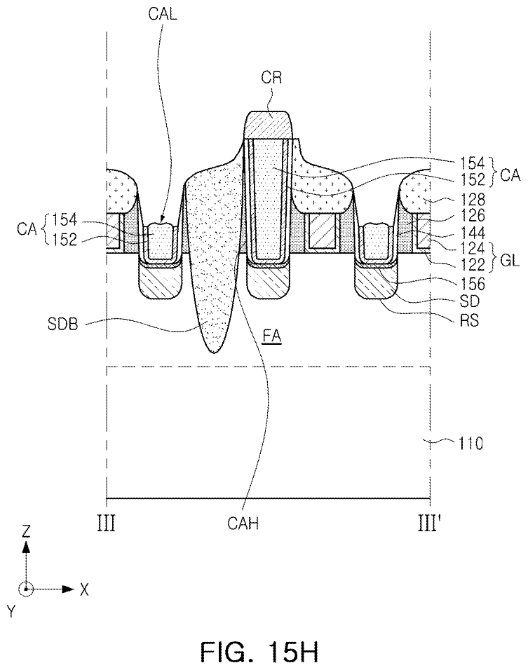

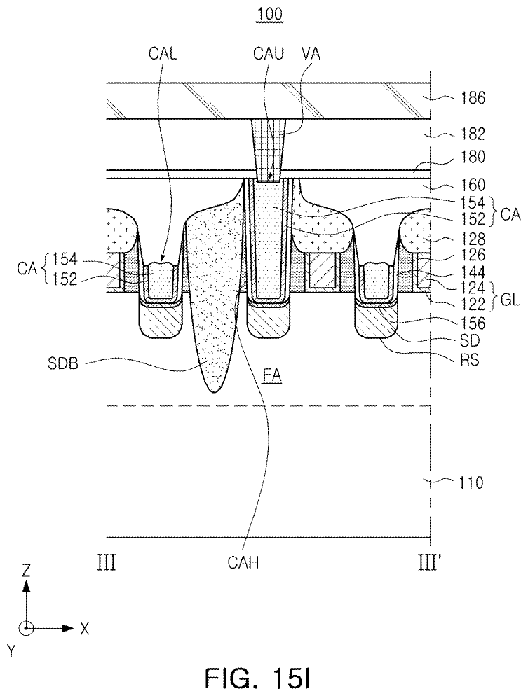

The source/drain contact CA may be disposed on the source/drain regions SD within the source/drain contact hole CAH penetrating the inter-gate insulating layer 145 (FIG. 15B). A contact liner 144 surrounding sidewalls of the source/drain contact CAH may be further disposed in the source/drain contact hole CAH. The contact liner 144 may include an insulating material.

The source/drain contact CA may include a conductive barrier layer 152 disposed on an inner wall of the source/drain contact hole CAH, and a contact plug 154 surrounded by the conductive barrier layer 152 and filling the source/drain contact hole CAH. The conductive barrier layer 152 may include at least one of, e.g., ruthenium (Ru), titanium (Ti), titanium nitride (TiN), tantalum (Ta), tantalum nitride (TaN), tungsten (W), titanium silicon nitride (TiSiN), titanium silicide (TiSi), and tungsten silicide (WSi). The contact plug 154 may include at least one of, e.g., tungsten (W), cobalt (Co), nickel (Ni), ruthenium (Ru), copper (Cu), aluminum (Al), silicides thereof, or alloys thereof. A metal-semiconductor compound layer 156 may be further disposed between the source/drain contact CA and the source/drain regions SD. An upper surface of the contact plug 154 may have an outwardly curved region and an inwardly curved region. An upper surface of the contact plug 154 may be disposed on a level higher than a level of an upper surface of the conductive barrier layer 152.

The source/drain contact CA may include a first source/drain contact CAL and a second source/drain contact CAU, and an upper surface of the second source/drain contact CAU may be disposed on a level, e.g., height, higher than a level of the upper surface of the source/drain contact CAL, e.g., relative to a bottom of the substrate 110. The upper surface of the first source/drain contact CAL may be disposed on a level lower than a level of the upper surface of the gate electrode 124, e.g., relative to a bottom of the substrate 110, and the upper surface of the second source/drain contact CAU may be disposed on a level higher than a level of the upper surface of the gate electrode 124, e.g., relative to the bottom of the substrate 110. For example, referring to FIGS. 1 and 3, the first source/drain contact CAL may have a linear shape in a top view (e.g., indicated by linear shapes with a dotted pattern in FIG. 1). For example, further referring to FIGS. 1 and 3, the second source/drain contact CAU may extend from some of the first source/drain contacts CAL in the second direction Y, and may extend above the first source/drain contacts CAL in the third direction Z (e.g., covered by a mask CR and a first upper contact VA in FIG. 1). For example, as illustrated in FIG. 3, the second source/drain contact CAU may continuously extend upward in the third direction Z from some of the first source/drain contacts CAL, e.g., so a sidewall of the contact plug 154 in the first source/drain contact CAL contacts the conductive barrier layer 152, and a sidewall of the contact plug 154 in the second source/drain contact CAU contacts the filling insulating layer 160.

The gate contact CB may be disposed to be connected to the gate electrode 124. For example, the gate contact CB may penetrate through the filling insulating layer 160 and the gate capping layer 128, and may be connected to the gate electrode 124. The gate contact CB may include a conductive barrier layer 172 and a contact plug 174 surrounded by the conductive barrier layer 172 and filling the internal region.

An etch stop film 180 and an interlayer insulating film 182 may be disposed on the source/drain contact CA, the filling insulating layer 160, and the gate contact CB. The etch stop film 180 may be formed of, e.g., silicon carbide (SiC), SiN, nitrogen-doped silicon carbide (SiC:N), SiOC, AlN, AlON, AlO, AlOC, or a combination thereof. The interlayer insulating film 182 may include, e.g., an oxide film, a nitride film, an ultra-low-x (ULK) film having an ultra-low dielectric constant K, or a combination thereof.

The separation structure SDB may be disposed on the substrate 110 to intersect the active patterns FA and to extend in the second direction Y. The separation structure SDB may extend in a direction perpendicular to the upper surface of the substrate 110, e.g., in the third direction Z. The separation structure SDB may be disposed between adjacent source/drain regions SD. The separation structure SDB may penetrate through the gate lines GL (e.g., see remaining portion of the gate spacer 126 on a sidewall of the separation structure SDB in FIG. 2) and may extend to the active patterns FA. The separation structure SDB may separate a plurality of transistors each including the gate lines GL and the source/drain regions SD from each other.

For example, the separation structure SDB may have an inclined side surface of which a width of a lower portion is narrower than a width of an upper portion depending on an aspect ratio. For example, the lower portion of the separation structure SDB may have a flat surface and may have an outwardly curved shape or a pointed shape toward the substrate 110.

The upper surface US of the separation structure SDB may be disposed on a level higher than a level of the upper surface of the gate electrode 124, e.g., relative to a bottom of the substrate 110. The lower end of the separation structure SDB may be disposed on a level lower than a level of the lower end of the source/drain regions SD, or may be disposed on a level higher than a level of the lower end of the active patterns FA, e.g., relative to a bottom of the substrate 110. In example embodiments, the lower end of the separation structure SDB may be disposed on a level higher than a level of the lower end of the active patterns FA by a predetermined depth (e.g., the lower end of the active patterns FA is seen in FIG. 3 and is indicated by the dashed line in FIG. 5). An upper surface US of the separation structure SDB may have a curved shape.

The separation structure SDB may be disposed between the first source/drain contact CAL and the second source/drain contact CAU (i.e., between the second source/drain contact CAU and a first source/drain contact CAL adjacent thereto in the first direction X). The upper surface US of the separation structure SDB may have at least one portion of which a level decreases toward the first source/drain contact CAL adjacent to a first side of the separation structure SDB and another portion of which a level increases toward the second source/drain contact CAU adjacent to a second side (i.e., opposite to the first side) of the separation structure SDB.

In detail, the upper surface US of the separation structure SDB may include a first portion US1 adjacent to the first source/drain contact CAL (and overlapping the first side of the separation structure SDB) and a second portion US2 adjacent to the second source/drain contact CAU (and overlapping the second side of the separation structure SDB that is opposite the first side), and the first portion US1 may be disposed on a level lower than a level of the second portion US2, e.g., relative to a bottom of the substrate 110. For example, as illustrated in FIG. 5, the first portion US1 may gradually curve downwardly toward the first source/drain contact CAL, and the second portion US2 may extend continuously from the first portion US1 in an upward direction toward the second source/drain contact CAU.

The separation structure SDB disposed between the first source/drain contact CAL and the second source/drain contact CAU may have an asymmetrical structure, e.g., with respect to a vertical axis along the third direction Z through a center of the separation structure SDB. In example embodiments, the separation structure SDB may include first to third separation structures. The first separation structure disposed between the first source/drain contact CAL and the second source/drain contact CAU may have an asymmetrical structure. The second separation structure adjacent to the first source/drain contact CAL may have a symmetrical structure. The third separation structure adjacent to the second source/drain contact CAU may have a symmetrical structure. The upper surface US of the separation structure SDB disposed between the first source/drain contact CAL and the second source/drain contact CAU may be in contact with the filling insulating layer 160 and the etch stop film 180.

The separation structure SDB may be disposed between adjacent source/drain regions SD and may prevent diffusion of impurities included in the adjacent source/drain regions SD. The separation structure SDB may be disposed adjacently in the first direction X, e.g., and may be disposed between the transistors including the source/drain regions SD and the gate lines GL and may isolate the transistors from each other.

The separation structure SDB may include an insulating material, e.g., at least one of SiO, SiN, SiCN, SiOC, SiON, and SiOCN. The separation structure SDB and the gate capping layer 128 may include different materials. For example, the gate capping layer 128 may include SiN, and the separation structure SDB may include SiOC.

The filling insulating layer 160 may be in contact with an upper surface of the first source/drain contact CAL, a sidewall of the second source/drain contact CAU, and the gate capping layer 128 (FIGS. 2 and 3). The filling insulating layer 160 may be in contact with at least a portion of the upper surface US of the separation structure SDB (FIG. 5). The lower surface of the filling insulating layer 160 may include at least one portion of which a level decreases toward the first source/drain contact CAL and another portion of which a level increases toward the second source/drain contact CAU, e.g., the lower surface of the filling insulating layer 160 may be complementary with respect to the upper surface US of the separation structure SDB. The filling insulating layer 160 may be recessed into the separation structure SDB and may extend in the third direction Z. The filling insulating layer 160 may include at least one of, e.g., SiOC, SiON, SiCN, SiN, Tonen silazene (TOSZ), tetraethyl orthosilicate (TEOS), ALD oxide, flowable chemical vapor deposition (FCVD) oxide, high density plasma (HDP) oxide, and plasma enhanced oxidation (PEOX) oxide.

The first upper contact VA may penetrate through the interlayer insulating film 182 and the etch stop film 180, and may be connected to the second source/drain contact CAU of the source/drain contact CA. The second upper contact VB may penetrate through the interlayer insulating film 182 and the etch stop film 180 and may be connected to the gate contact CB.

A wiring layer 186 may be disposed on the first upper contact VA and the second upper contact VB. For example, the wiring layer 186 may include a power line configured to apply a power supply voltage to the source/drain regions SD through the source/drain contact CA, a ground line configured to apply a ground voltage to the source/drain regions SD through the source/drain contact CA, and a signal line arranged in parallel to the power line and the ground line and connected to at least one of the source/drain contact CA and the gate contact CB.

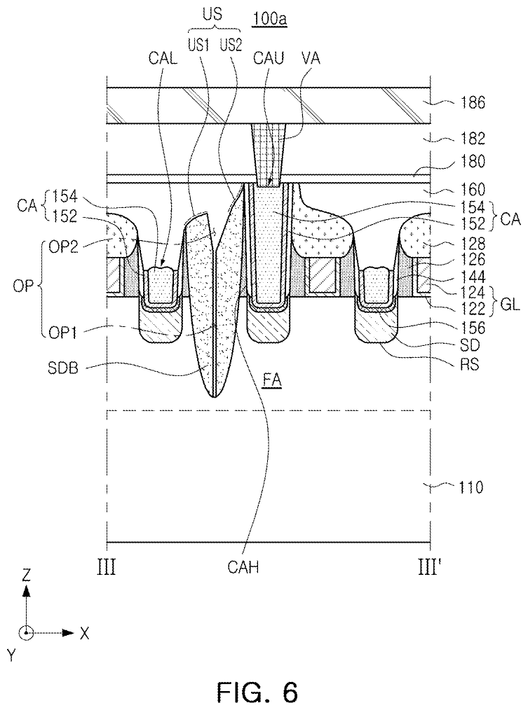

FIG. 6 is a cross-sectional view of a semiconductor device 100a according to an example embodiment, illustrating a region corresponding to FIG. 5.

Referring to FIG. 6, differently from the example embodiment in FIGS. 1 to 5, an opening OP may be disposed in the separation structure SDB. The opening OP is a part of a “seam” generated in the process of forming the separation structure (see FIG. 15F), and may have a structure that at least partially extends in the second direction. Y As shown in FIG. 6, the opening OP extends in the third direction Z toward the substrate 110, and the opening OP extends in the separation structure SDB. The opening OP can be shown as a gap between the first portion US1 and the second portion US2. The filling insulating layer 160 may fill the opening OP. The opening OP may include the same material as a material of the filling insulating layer 160. The opening OP may include a first opening OP1 and a second opening OP2 disposed on the first opening OP1. The second opening OP2 may be an upper part of the seam partially removed and/or enlarged during a recess process (see FIG. 15H). The first opening OP1 may be a remaining portion of the seam connected to the second opening OP2. The width of the second opening OP2 may decrease downwardly. The sidewall of the first opening OP1 and the sidewall of the second opening OP2 may have different slopes. For example, the sidewall of the second opening OP2 may have a steeper slope than that of the sidewall of the first opening OP1.

Other than the configurations described above, the semiconductor device 100a according to the example embodiment may have a structure similar to that of the semiconductor device 100 illustrated in FIGS. 1 to 5. Also, the components in the example embodiment may be understood with reference to the descriptions of the same or similar elements of the semiconductor device 100 illustrated in FIGS. 1 to 5 unless otherwise indicated.

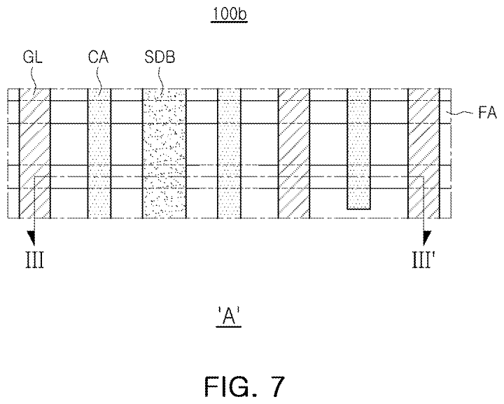

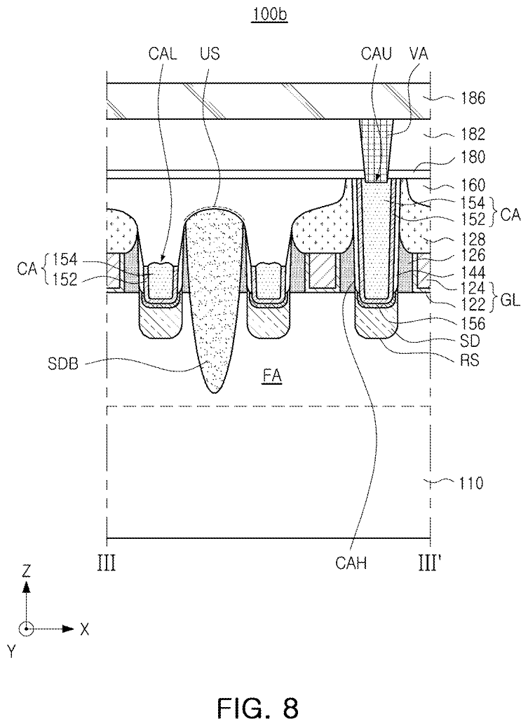

FIG. 7 is an enlarged plan view of a portion of a semiconductor device 100b according to an example embodiment, illustrating a region corresponding to FIG. 4. FIG. 8 is a cross-sectional view along line in FIG. 7.

Referring to FIGS. 7 and 8, differently from the example embodiment in FIGS. 1 to 5, the first source/drain contact CAL may be disposed adjacent to the separation structure SDB. That is, the separation structure SDB may be between two first source/drain contacts CAL. The separation structure SDB disposed adjacent to the first source/drain contact CAL may have a symmetrical structure. An upper surface US of the separation structure SDB disposed adjacent to the first source/drain contact CAL may be in contact with the filling insulating layer 160 and may be spaced apart from the etch stop film 180.

Other than the configurations described above, the semiconductor device 100b according to the example embodiment may have a structure similar to that of the semiconductor device 100 illustrated in FIGS. 1 to 5. Also, the components of the example embodiment may be understood with reference to the descriptions of the same or similar components of the semiconductor device 100 illustrated in FIGS. 1 to 5 unless otherwise indicated.

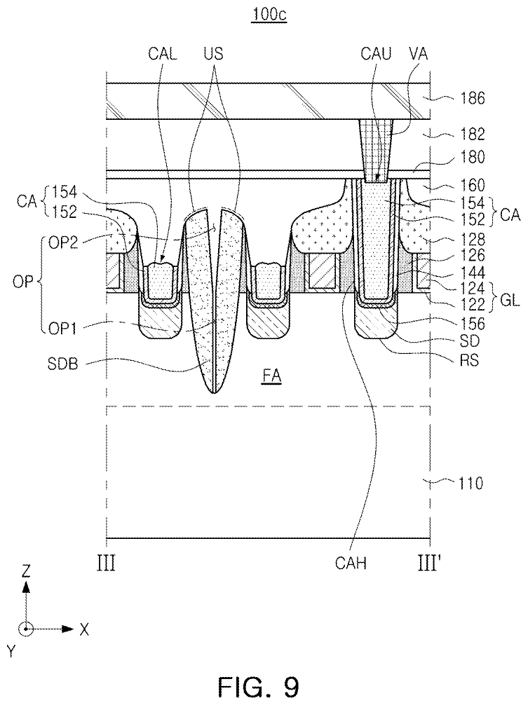

FIG. 9 is a cross-sectional view of a semiconductor device 100c according to an example embodiment, illustrating a region corresponding to FIG. 8.

Referring to FIG. 9, differently from the example embodiments in FIGS. 7 and 8, an opening OP may be disposed in the separation structure SDB. The opening OP may include the same material as that of the filling insulating layer 160 and may be integrally connected to the filling insulating layer 160. The opening OP may include a first opening OP1 and a second opening OP2 disposed on the first opening OP1. The width of the second opening OP2 may decrease downwardly, and the maximum width of the second opening OP2 may be greater than the maximum width of the first opening OP1.

Other than the configurations described above, the semiconductor device 100c according to the example embodiment may have a structure similar to that of the semiconductor device 100b illustrated in FIGS. 7 and 8. Also, the components of the example embodiment may be understood with reference to the descriptions of the same or similar components of the semiconductor device 100b illustrated in FIGS. 7 and 8 unless otherwise indicated.

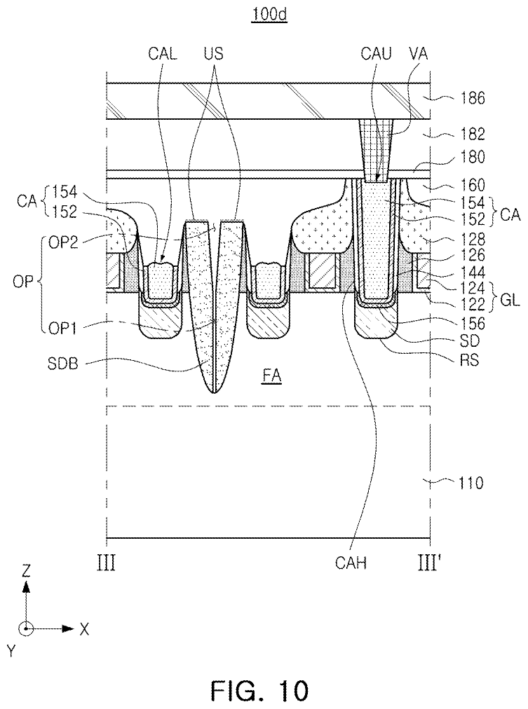

FIG. 10 is a cross-sectional view of a semiconductor device 100d according to an example embodiment, illustrating a region corresponding to FIG. 8.

Referring to FIG. 10, differently from the example embodiment in FIG. 9, the upper surface US of the separation structure SDB may have a planar shape, e.g., parallel to the bottom of the substrate 110. The upper surface US of the separation structure SDB may be disposed on substantially the same level as a level of the upper surface of the opening OP.

Other than the configurations described above, the semiconductor device 100d according to the example embodiment may have a structure similar to that of the semiconductor device 100c illustrated in FIG. 9. Also, the components of the example embodiment may be understood with reference to the descriptions of the same or similar components of the semiconductor device 100c illustrated in FIGS. 7 and 8 unless otherwise indicated.

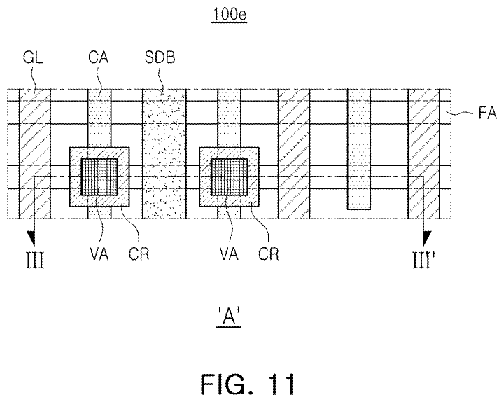

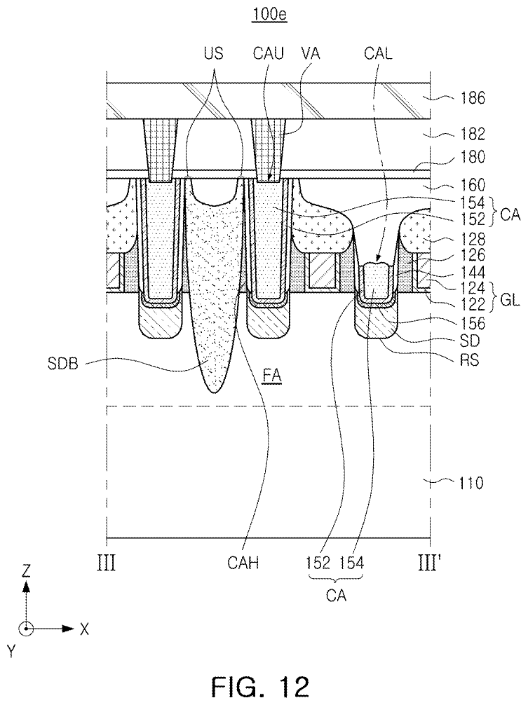

FIG. 11 is an enlarged plan view of a portion of a semiconductor device 100e according to an example embodiment, illustrating a region corresponding to FIG. 4. FIG. 12 is a cross-sectional view along line in FIG. 11.

Referring to FIGS. 11 and 12, differently from the example embodiment in FIGS. 1 to 5, the second source/drain contact CAU may be disposed adjacent to the separation structure SDB. That is, the separation structure SDB may be between two second source/drain contacts CAU. The separation structure SDB disposed adjacent to the second source/drain contact CAU may have a symmetrical structure. An upper surface US of the separation structure SDB may be disposed on substantially the same level as a level of an upper surface of the second source/drain contact CAU, e.g., an uppermost surface of the separation structure SDB may be coplanar with an uppermost surface of the second source/drain contact CAU.

Other than the configurations described above, the semiconductor device 100e according to the example embodiment may have a structure similar to that of the semiconductor device 100 illustrated in FIGS. 1 to 5. Also, the components of the example embodiment may be understood with reference to the descriptions of the same or similar components of the semiconductor device 100 illustrated in FIGS. 1 to 5 unless otherwise indicated.

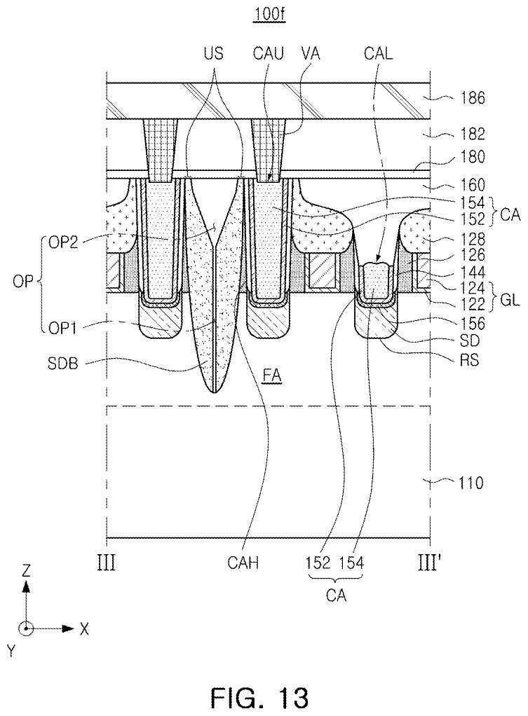

FIG. 13 is a cross-sectional diagram of a semiconductor device 100f according to an example embodiment, illustrating a region corresponding to FIG. 11.

Referring to FIG. 13, differently from the example embodiments in FIGS. 11 and 12, an opening OP may be disposed in the separation structure SDB. The opening OP may include the same material as that of the filling insulating layer 160 and may be integrally connected to the filling insulating layer 160. The opening OP may include a first opening OP1 and a second opening OP2 disposed on the first opening OP1. The width of the second opening OP2 may decrease downwardly, and the maximum width of the second opening OP2 may be greater than the maximum width of the first opening OP1.

Other than the configurations described above, the semiconductor device 100f according to the example embodiment may have a structure similar to that of the semiconductor device 100e illustrated in FIGS. 11 and 12. Also, the components of the example embodiment may be understood with reference to the descriptions of the same or similar components of the semiconductor device 100e illustrated in FIGS. 11 and 12 unless otherwise indicated.

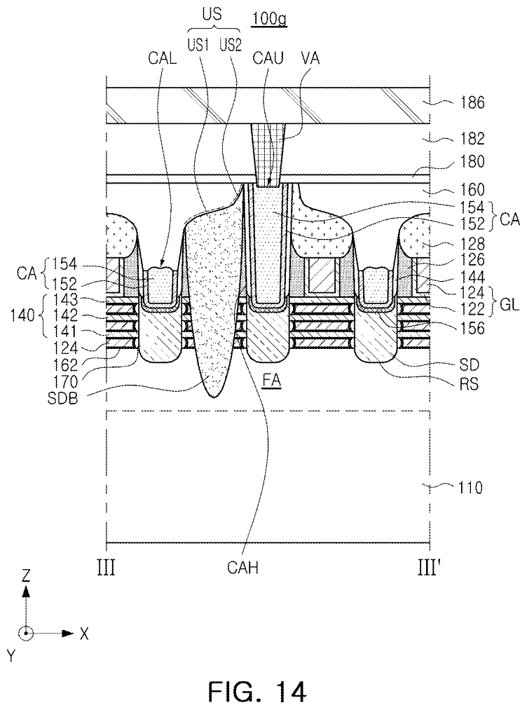

FIG. 14 is a cross-sectional diagram illustrating a semiconductor device 100g according to an example embodiment.

Referring to FIG. 14, differently from the example embodiment in FIGS. 1 to 5, the semiconductor device 100g may further include a channel structure 140, a gate dielectric layer 162, and internal spacer layers 170.

The channel structure 140 may include first to third channel layers 141, 142, and 143, two or more channel layers spaced apart from each other in a direction perpendicular to the upper surface of the active patterns FA, e.g., in the third direction Z on the active patterns FA. The first to third channel layers 141, 142, and 143 may be spaced apart from upper surfaces of the active patterns FA while being connected to the source/drain regions SD. For example, the first to third channel layers 141, 142, and 143 may have a same or similar width to that of the active patterns FA in the second direction Y, and have a same or similar width to that of the gate lines GL in the first direction X. In another example, the first to third channel layers 141, 142, and 143 may have a reduced width such that side surfaces may be disposed below the gate lines GL in the first direction X.

The first to third channel layers 141, 142, and 143 may be formed of a semiconductor material, e.g., at least one of silicon (Si), silicon germanium (SiGe), and germanium (Ge). For example, the first to third channel layers 141, 142, and 143 may be formed of the same material as that of the substrate 110. In example embodiments, the first to third channel layers 141, 142, and 143 may include impurity regions disposed adjacent to the source/drain regions SD. The number of the channel layers 141, 142, and 143 included in one channel structure 140 and shapes thereof may be varied in embodiments. For example, the channel structure 140 may further include a channel layer disposed on upper surfaces of the active patterns FA.

The gate dielectric layer 162 may be disposed between the active patterns FA and the gate electrode 124 and between the channel structure 140 and the gate electrode 124, and may be disposed to cover at least a portion of the surfaces of the gate electrode 124. For example, the gate dielectric layer 162 may be disposed to surround overall surfaces of the gate electrode 124 other than the uppermost surface. The gate dielectric layer 162 may extend to a region between the gate electrode 124 and the gate spacer layers 164. The gate dielectric layer 162 may include an oxide, nitride, or high-x material. The high-x material may refer to a dielectric material having a higher dielectric constant than that of silicon oxide (SiO₂). The high dielectric constant material may be one of, e.g., aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The internal spacer layers 170 may be disposed parallel to the gate electrode 124 between the channel structures 140. The internal spacer layers 170 may have external side surfaces substantially coplanar with external side surfaces of the first to third channel layers 141, 142, and 143. Below the third channel layer 143, the gate electrode 124 may be spaced apart from the source/drain regions SD by internal spacer layers 170 and may be electrically isolated from each other. The internal spacer layers 170 may have a shape in which a side surface thereof opposing the gate electrode 124 may be inwardly rounded toward the gate electrode 124. The internal spacer layers 170 may be formed of oxide, nitride, and oxynitride, and may include, e.g., a low-K film.

Other than the configurations described above, the semiconductor device 100g according to the example embodiment may have a structure similar to that of the semiconductor device 100 illustrated in FIGS. 1 to 5. Also, the components in the example embodiment may be understood with reference to the descriptions of the same or similar components of the semiconductor device 100 illustrated in FIGS. 1 to 5 unless otherwise indicated.

FIGS. 15A to 15I are cross-sectional views illustrating stages in a method of manufacturing a semiconductor device according to an example embodiment. FIGS. 15A to 15I correspond to the region in FIG. 3.

Referring to FIG. 15A, a device isolation layer (112 in FIGS. 2 and 3) may be formed on the upper surface of the substrate 110 to define the active patterns FA. In example embodiments, the device isolation layer 112 may be formed of an insulating material, e.g., silicon oxide and/or silicon nitride.

Referring to FIG. 15B, sacrificial gate lines DGL may be formed on the substrate 110. Each of the sacrificial gate lines DGL may include a sacrificial gate insulating layer pattern 322, a sacrificial gate 324, and a hard mask pattern 326 sequentially stacked.

Gate spacers 126 may be formed on sidewalls of the sacrificial gate lines DGL. The gate spacers 126 may include, e.g., silicon nitride.

Recess regions RS may be formed by partially etching the active patterns FA using the sacrificial gate lines DGL as an etch mask. Source/drain regions SD may be formed in the recess regions RS between the sacrificial gate lines DGL.

In example embodiments, the source/drain regions SD may be formed by an epitaxial process using the active patterns FA exposed on inner walls of the recess regions RS as seed layers. An insulating layer covering the sacrificial gate lines DGL may be formed, and an inter-gate insulating layer 145 may be formed by planarizing the insulating layer until the upper surface of the hard mask pattern 326 is exposed.

Referring to FIG. 15C, gate spaces GS may be formed by removing the sacrificial gate lines DGL.

Referring to FIG. 15D, an insulating layer 122L may be, e.g., conformally, formed on inner walls of the gate spaces GS. Thereafter, a conductive layer 124L filling the gate space may be formed on the insulating layer 122L.

Referring to FIG. 15E, the gate electrode 124 may be formed by planarizing an upper portion of the conductive layer 124L until the upper surface of the inter-gate insulating layer 145 is exposed. In this case, a portion of the insulating layer 122L formed on the upper surface of the inter-gate insulating layer 145 may also be removed and the gate insulating layer 122 may be formed. Thereafter, the upper entrances of the gate spaces GS may be laterally expanded by etching back the upper portions of the gate electrodes 124 and the upper portions of the gate spacers 126, and a gate capping layer 128 filling the upper entrances of the gate spaces GS may be formed.

Referring to FIG. 15F, a trench (not illustrated) may be formed by etching a portion of the gate lines GL and the gate capping layer 128, and etching the active patterns FA below a portion of the gate lines GL. A separation structure SDB may be formed by filling the trench with an insulating material and performing planarization through a chemical mechanical polishing (CMP) process.

Referring to FIG. 15G, source/drain contact holes CAH exposing upper surfaces of the source/drain regions SD may be formed by etching a portion of the inter-gate insulating layer 145. Thereafter, the contact liner 144 conformally covering the inner wall of the source/drain contact hole CAH may be formed on the gate capping layer 128 and the inter-gate insulating layer 145, and a conductive barrier layer 152 may be formed on an inner wall of the source/drain contact hole CAH.

In an example, a metal-semiconductor compound layer 156 may be formed between the conductive barrier layer 152 and the source/drain regions SD. Thereafter, a metal film filling the source/drain contact hole CAH may be formed on the conductive barrier layer 152, and the top of the metal film may be planarized such that the upper surfaces of the inter-gate insulating layer 145 and the gate capping layer 128 may be exposed, thereby forming the contact plug 154.

Referring to FIG. 15H, a mask pattern CR covering a portion of the source/drain contact CA may be formed. In example embodiments, an etch stop film, e.g., formed of SiOC, SiN, or a combination thereof, may be formed on a portion of the source/drain contact CA, and the mask pattern CR may be formed on the etch stop film. The mask pattern CR may include, e.g., a silicon oxide film, a spin on hardmask (SOH) film, a photoresist film, or a combination thereof. A portion of the upper side of the source/drain contact CA not covered by the mask pattern CR may be removed by performing a recess process for etching the source/drain contact CA using the mask pattern CR as an etch mask. By the recess process, the source/drain contact CA may be formed to include the second source/drain contact CAU and the first source/drain contact CAL having upper surfaces at different levels. The second source/drain contact CAU may be the portion covered by the mask pattern CR and having a level not lowered in the recess process, and the first source/drain contact CAL may be the portion having a level reduced by being exposed to an etching atmosphere in the recess process. A portion of the upper side of the gate capping layer 128 may be removed together by the recess process, such that the gate capping layer 128 may have an outwardly curved upper surface. Also, in the recess process, a portion of the level of the inter-gate insulating layer 145 may be removed together.

Referring to FIG. 15I, the filling insulating layer 160 may be formed on exposed surfaces of the source/drain contact CA, the gate capping layer 128, and the inter-gate insulating layer 145, and an upper side of the filling insulating layer 160 may be planarized to expose the second source/drain contact CAU of the drain contact CA. The filling insulating layer 160 may be formed to completely fill an upper side of the source/drain contact hole CAH exposed on the first source/drain contact CAL of the source/drain contact CA. An etch stop film 180 may be formed on the filling insulating layer 160, the source/drain contact CA, and the gate contact CB, and an interlayer insulating film 182 may be formed on the etch stop film 180. Thereafter, a via hole penetrating through the interlayer insulating film 182 and the etch stop film 180 may be formed, and a conductive via 184 may be formed by filling the via hole with a metal material. A wiring layer 186 may be formed on the conductive via 184. Accordingly, the semiconductor device 100 in FIGS. 1 to 5 may be manufactured.

By way of summation and review, example embodiments provide a semiconductor device having improved electrical properties. That is, according to the aforementioned example embodiments, by including a separation structure adjacent to the first source/drain contact and/or the second source/drain contact disposed at a level higher than a level of the upper surface of the first source/drain contact, and having a symmetrical structure or an asymmetrical structure, a semiconductor device having improved electrical properties may be provided. In other words, a portion of the source/drain contact (e.g., active contact) may be recessed, and the shape of the separation structure (e.g., diffusion break) may be varied in accordance with the shape of the adjacent source/drain contact.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
an active pattern disposed on a substrate, the active pattern including a first region and a second region;
a first source/drain region on the first region and a second source/drain region on the second region;
a first source/drain contact on the first source/drain region;
a second source/drain contact on the second source/drain region; and
a separation structure intersecting the active pattern between the first source/drain contact and the second source/drain contact, the separation structure extending into the active pattern between the first source/drain region and the second source/drain region,
wherein an upper surface of the second source/drain contact is higher than an upper surface of the first source/drain contact, and
wherein the separation structure has an asymmetrical structure, an upper surface of a first portion of the separation structure adjacent to the first source/drain contact being higher than an upper surface of a second portion of the separation structure adjacent to the second source/drain contact.

2. The semiconductor device as claimed in claim 1, wherein a height of the upper surface of the second portion increases toward the second source/drain contact.

3. The semiconductor device as claimed in claim 1, further comprising an upper contact on the upper surface of the second source/drain contact, the upper contact being connected to the second source/drain contact.

4. The semiconductor device as claimed in claim 1, further comprising an insulating layer in contact with an upper surface of the separation structure, the insulating layer extending onto the upper surface of the first source/drain contact.

5. The semiconductor device as claimed in claim 1, wherein the first source/drain contact includes a contact plug and a conductive barrier layer.

6. The semiconductor device as claimed in claim 5, wherein an upper surface of the contact plug has a convex or concave region.

7. The semiconductor device as claimed in claim 6, wherein the upper surface of the contact plug is at a level higher than a level of a top of the conductive barrier layer.

8. The semiconductor device as claimed in claim 1, wherein the separation structure includes an opening extending between the first portion and the second portion in a vertical direction perpendicular to an upper surface of the substrate.

9. The semiconductor device as claimed in claim 8, further comprising an insulating layer on an upper surface of the separation structure, the insulating layer filling the opening.

10. The semiconductor device as claimed in claim 9, wherein the opening includes a first opening having a first width and a second opening on the first opening and having a second width, which is greater than the first width.

11. The semiconductor device as claimed in claim 10, wherein the second width of the second opening decreases downwardly.

12. The semiconductor device as claimed in claim 10, wherein a sidewall of the second opening has a steeper slope than that of a sidewall of the first opening.

13. The semiconductor device as claimed in claim 1, further comprising:
channel layers stacked and spaced apart from each other in a vertical direction on the active pattern; and
a gate structure surrounding each of the channel layers and extending in a second direction perpendicular to that of the active pattern.

14. A semiconductor device, comprising:
active patterns extending in a first direction on a substrate;
source/drain regions on the active patterns;
source/drain contacts respectively on the source/drain regions; and
a separation structure extending in a second direction intersecting the first direction, the separation structure being between adjacent ones of the source/drain contacts, and the separation structure extending into the active patterns between a first source/drain region and a second source/drain region of the source/drain regions in a vertical direction perpendicular to an upper surface of the substrate,
wherein the adjacent ones of the source/drain contacts include first and second source/drain contacts adjacent to each other in the first direction, and third and fourth source/drain contacts adjacent to each other in the first direction,
wherein an upper surface of the second source/drain contact is higher than an upper surface of the first source/drain contact, and an upper surface of the third source/drain contact has substantially a same height as an upper surface of the fourth source/drain contact,
wherein the separation structure includes a first separation structure between the first and second source/drain contacts, and a second separation structure between the third and fourth source/drain contacts, and
wherein, in a cross section along the first direction, the first separation structure has an asymmetric structure, and the second separation structure has a symmetrical structure.

15. The semiconductor device as claimed in claim 14, further comprising an insulating layer and an etch stop film stacked on the first source/drain contact and the second source/drain contact, an upper surface of the first separation structure being in contact with the insulating layer and the etch stop film.

16. The semiconductor device as claimed in claim 15, wherein:
the upper surfaces of the third and fourth source/drain contacts are lower than the upper surface of the second source/drain contact, and
an upper surface of the second separation structure is in contact with the insulating layer and is spaced apart from the etch stop film.

17. The semiconductor device as claimed in claim 16, wherein the upper surface of the second separation structure has a curved shape.

18. The semiconductor device as claimed in claim 15, wherein:
the upper surfaces of the third and fourth source/drain contacts are at a same height as the upper surface of the second source/drain contact, and
an upper surface of the second separation structure has a first portion in contact with the insulating layer and is spaced apart from the etch stop film, and a second portion in contact with the etch stop film.

19. The semiconductor device as claimed in claim 18, wherein the second portion of the upper surface of the second separation structure is adjacent to at least one of the third and fourth source/drain contacts.

20. A semiconductor device, comprising:
an active pattern on a substrate, the active pattern extending in a first direction;
a gate structure crossing the active pattern, the gate structure extending in a second direction intersecting the first direction;
a separation structure intersecting the active pattern, the separation structure extending in a vertical direction perpendicular to an upper surface of the substrate;
a first source/drain region on the active pattern between the gate structure and a first side of the separation structure;
a second source/drain region on the active pattern at a second side of the separation structure;
a first source/drain contact on the first source/drain region; and
a second source/drain contact on the second source/drain region,
wherein one of the first and second source/drain contacts has an upper surface higher than an upper surface of the gate structure, and the other of the first and second source/drain contacts has an upper surface lower than the upper surface of the gate structure, and
wherein the separation structure has a symmetrical structure in which an upper surface of a first portion adjacent to the one of the first and second source/drain contacts is higher than an upper surface of a second portion adjacent to the other of the first and second source/drain contacts.
